(19) United States
(12) Patent Application Publication
(10) Pub. No.: US 2019/0181155 A1
(43) Pub. Date: Jun. 13, 2019

(54) DISPLAY SUBSTRATE AND MANUFACTURING METHOD THEREOF, AND DISPLAY PANEL

(71) Applicant: BOE Technology Group Co., Ltd., Beijing (CN)

(72) Inventors: Yunfei Li, Beijing (CN); Lujiang Huangfu, Beijing (CN); Yipeng Chen, Beijing (CN); Jianchao Zhu, Beijing (CN)

(73) Assignee: BOE TECHNOLOGY GROUP CO., LTD.

(21) Appl. No.: 16/049,958

(22) Filed: Jul. 31, 2018

(30) Foreign Application Priority Data
Dec. 11, 2017 (CN) 201711305470.9

(51) Int. Cl. H01L 27/12; H01L 29/786

(52) U.S. Cl. CPC H01L 27/124; H01L 27/3276; H01L 27/1262; H01L 29/78633

(57) ABSTRACT

A display substrate and a manufacturing method thereof, and a display panel are provided. The display substrate includes at least one set of signal lines and at least one shielding structure disposed on a base substrate. The shielding structure is electrically connected to a DC power source. The shielding structure includes a shielding portion. Each set of signal lines includes a first signal line and a second signal line at different layers. Orthographic projections of first signal line and second signal line on base substrate overlap and have an overlapping region. Shielding portion is located between the first signal line and the second signal line, and insulated from the two signal lines. An orthographic projection of the shielding portion on base substrate at least partially overlaps the overlapping region. Since voltage on shielding structures is stable, thereby effectively avoiding crosstalk between the two signal lines in set of signal lines.

This application claims priority to Chinese Patent Application No. 201711305470.9 filed with the State Intellectual Property Office on Dec. 11, 2017 and titled “Display substrate and manufacturing method thereof, and display panel”, the entire contents of which are incorporated herein by reference.

### TECHNICAL FIELD

The present disclosure relates to a display substrate and a manufacturing method thereof, and a display panel.

### BACKGROUND

Organic Light Emitting Diode (OLED) display panels have been widely used due to their characteristics of self-illumination, low drive voltage, fast response, and the like.

In the related art, an OLED device in an OLED display panel needs to be driven by a pixel circuit which generally includes a drive transistor, a switching transistor, and a storage capacitor. Each of the transistors therein is connected to a plurality of signal lines for operating under the control of the drive signals transmitted by the plurality of signal lines.

Since the signal lines disposed in the OLED display panel have a large number and a high density, the crosstalk may be occurred between adjacent signal lines, which affects the display effect of the display panel.

### SUMMARY

There are provided in the present disclosure a display substrate and a manufacturing method thereof, and a display panel.

In an aspect, there is provided a display substrate, including:
at least one set of signal lines and at least one shielding structure corresponding to the at least one set of signal lines disposed on a base substrate, the shielding structure being electrically connected to a DC power source, and the shielding structure including a shielding portion,
where each set of signal lines includes a first signal line and a second signal line that are located at different layers, and orthographic projections of the first signal line and the second signal line on the base substrate overlap and have an overlapping region; and
the shielding portion is located between the first signal line and the second signal line, and is insulated from both the first signal line and the second signal line, and an orthographic projection of the shielding portion on the base substrate at least partially overlaps the overlapping region.

Optionally, the orthographic projection of the shielding portion on the base substrate covers the overlapping region.

Optionally, the display substrate father includes: a plurality of transistors disposed on the base substrate, where at least one signal line of each set of signal lines is connected to a gate of at least one of the transistors.

Optionally, the shielding structure further includes a lead portion electrically connected to the DC power source and the shielding portion, respectively, the lead portion is disposed in the same layer as the shielding portion, or the lead portion is disposed in a different layer from the shielding portion, and the shielding portion is connected to the lead portion through a via hole.

Optionally, the lead portion and a signal line for transmitting a non-DC signal in the display substrate are parallel to each other.

Optionally, the lead portion and the data signal line in the display substrate are parallel to each other.

Optionally, the display substrate includes: a plurality of shielding structures; where at least two of the plurality of shielding structures share one lead portion.

Optionally, the shielding structure is electrically connected to the DC power source through a DC signal line in the display substrate.

Optionally, the shielding structure is made of a metal material, and resistivity of the metal material is less than a preset threshold value.

Optionally, a first insulating layer is arranged between a first signal line of each set of signal lines and the corresponding shielding portion in the shielding structure; and a second insulating layer is arranged between a second signal line of each set of signal lines and the corresponding shielding portion.

In another aspect, there is provided a method for manufacturing a display substrate, including steps of:
forming at least one set of signal lines and at least one shielding structure corresponding to the at least one set of signal lines on a base substrate, the shielding structure including a shielding portion; and
electrically connecting the shielding structure to a DC power source,
where each set of signal lines includes a first signal line and a second signal line that are located at different layers, and orthographic projections of the first signal line and the second signal line on the base substrate overlap and have an overlapping region; and
the shielding portion is located between the first signal line and the second signal line, and is insulated from both the first signal line and the second signal line, and an orthographic projection of the shielding portion on the base substrate at least partially overlaps the overlapping region.

Optionally, the orthographic projection of the shielding portion in the shielding structure on the base substrate covers the overlapping region.

Optionally, a plurality of transistors are further formed on the base substrate; and at least one signal line in each set of signal lines is formed in the same layer as a gate of at least one of the transistors and is connected to the gate.

Optionally, the step of forming at least one set of signal lines and at least one shielding structure corresponding to the at least one set of signal lines on the base substrate includes:
forming a first signal line on the base substrate;
forming a first insulating layer on a side of the first signal line away from the base substrate;
forming a shielding portion in the shielding structure on the side of the first insulating layer away from the base substrate;
forming a second insulating layer on a side of the shielding portion away from the base substrate; and
forming a second signal line on a side of the second insulating layer away from the base substrate,
where the first signal line and the second signal line constitute the set of signal

Optionally, the step of forming the shielding structure on the base substrate further includes steps of:
forming a lead portion in the shielding structure on the base substrate, the lead portion being electrically connected to the DC power source and the shielding portion, respectively;
where the lead portion is formed in the same layer as the shielding portion, or the lead portion is formed in a different layer from the shielding portion, and the shielding portion is connected to the lead portion through a via hole.

Optionally, the step of forming the shielding structure on the base substrate further includes steps of:
forming the lead portion when the first signal line is formed; or forming the lead portion when the second signal line is formed.

In yet another aspect, there is provided a display panel, including: the display substrate described in the above aspects.

In still yet another aspect, there is provided a display device: including the display panel described in the above aspects.

There are provided in the embodiments of the present disclosure a display substrate, a manufacturing method thereof and a display panel. The display substrate includes at least one shielding structure. A shielding portion in the shielding structure is located between a first signal line and a second signal line in a set of signal lines. An orthographic projection of the shielding portion on the base substrate at least partially overlaps with an overlapping region formed by the two signal lines on the base substrate.

### BRIEF DESCRIPTION OF THE DRAWINGS

FIG. 1 is a schematic diagram of a structure of a display substrate provided in an embodiment of the present disclosure;

FIG. 2 is a cross-sectional view of the display substrate shown in FIG. 1 in a direction AA;

FIG. 3 is a schematic diagram of a structure of another display substrate provided in an embodiment of the present disclosure;

FIG. 4 is a schematic diagram of a structure of yet another display substrate provided in an embodiment of the present disclosure;

FIG. 5 is a schematic diagram of a structure of still yet another display substrate provided in an embodiment of the present disclosure;

FIG. 6 is a schematic diagram of a structure of still yet another display substrate provided in an embodiment of the present disclosure;

FIG. 7 is a flowchart of a method for manufacturing a display substrate provided in an embodiment of the present disclosure; and

FIG. 8 is a flowchart of a method for forming a set of signal lines and a corresponding shielding line provided in an embodiment of the present disclosure.

### DETAILED DESCRIPTION

The present disclosure will be described in further detail with reference to the enclosed drawings, to clearly present the principles and advantages of the present disclosure.

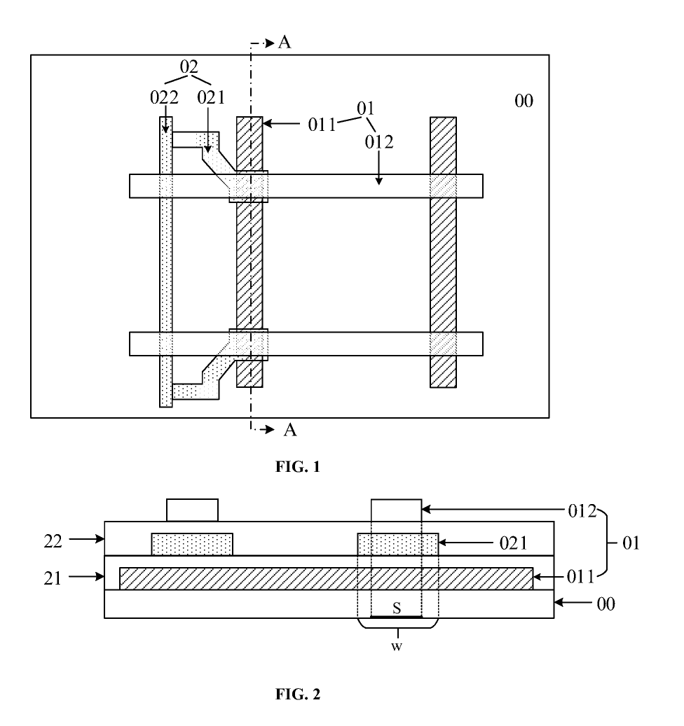

FIG. 1 is a schematic diagram of a structure of a display substrate provided in an embodiment of the present disclosure. As shown in FIG. 1, the display substrate may include: at least one set of signal lines 01 and at least one shielding structure 02 corresponding to the at least one set of signal lines 01 disposed on a base substrate 00. Each of the shielding structures 02 may be electrically connected to a DC power source (not shown in the figure), and each of the shielding structures 02 may include a shielding portion 021.

FIG. 2 is a cross-sectional view of the display substrate shown in FIG. 1 in a direction AA. It can be known in connection with FIG. 2 that each set of signal lines 01 may include a first signal line 011 and a second signal line 012 located at different layers. An orthographic projection of the first signal line 011 on the base substrate 00 and an orthographic projection of the second signal line 012 on the base substrate 00 overlap and have an overlapping region S.

The shielding portion 021 in each shielding structure 02 is located between the first signal fine 011 and the second signal line 012 in the corresponding set of signal lines, and is insulated from both of the first signal line 011 and the second signal line 012. In addition, an orthographic projection W of the shielding portion 021 in each shielding structure 02 on the base substrate 00 at least partially overlaps the overlapping region S formed by the corresponding set of signal lines 01 on the base substrate 00.

If two signal lines in a display panel are located in different layers, but the orthographic projections thereof on a base substrate overlap, the two signal lines may form a parasitic capacitance. When the voltage on one of the signal lines changes, the voltage on the other signal line also changes, which affects the display effect of the display device. In the embodiments of the present disclosure, a shielding structure electrically connected to a DC power source is disposed in a display substrate, and a shielding portion in the shielding structure is disposed between the two signal lines, so that the shielding portion can respectively form a parasitic capacitance with each signal line. When the voltage (or current) on a signal line changes, it will affect the voltage (or current) on the shielding portion. However, since the shielding portion is electrically connected to the DC power source, the voltage (or current) thereof is relatively stable, and the fluctuation after being affected is small, so that the influence of the voltage (or current) fluctuation of the shielding portion on the other signal line is also reduced, thereby effectively reducing the crosstalk between the two signal lines.

In summary, there is provided in the embodiments of the present disclosure a display substrate. The display substrate includes at least one shielding structure. A shielding portion in each shielding structure is located between two signal lines in a set of signal lines. An orthographic projection of the shielding portion on the base substrate at least partially overlaps with an overlapping region formed by the orthographic projections of the two signal lines on the base substrate. Since the shielding structure is electrically connected to the DC power source, the voltage and current on the shielding structure are relatively stable, thereby effectively reducing the crosstalk between the two signal lines included in the set of signal lines, and ensuring the display effect of the display device.

Optionally, as can be seen from FIG. 1 and FIG. 2, the orthographic projection W of the shielding portion 021 in each shielding structure 02 on the base substrate 00 can cover the overlapping region S of the corresponding set of signal lines 01.

The overlapping region S formed by the orthographic projections of the two signal lines in each set of signal lines 01 on the base substrate 00 may be located within the orthographic projection W of the corresponding shielding portion 021 on the base substrate 00. At this time, each of the shielding portions 021 can effectively isolate the first signal line 011 and the second signal line 012 in the set of signal lines 01, and avoid forming a parasitic capacitance between the first signal line 011 and the second signal line 012, thereby further reducing a probability of crosstalk between the first signal line 011 and the second signal line 012, and ensuring the display effect of the display device.

Optionally, in the embodiments of the present disclosure, a trace pattern of the shielding portion 021 in each of the shielding structures 02 may be determined according to a trace pattern of a corresponding set of signal lines 01. On the premise that the orthographic projection of the shielding portion 021 on the base substrate 00 at least partially overlap with the corresponding overlapping region S, an overlapping region formed by the orthographic projection of the shielding portion 021 on the base substrate 00 and the orthographic projection of any signal line on the base substrate should be reduced as much as possible, so as to reduce the crosstalk additionally introduced by the shielding portion as much as possible.

Optionally, the display substrate may further include a plurality of transistors disposed on the base substrate 00. Each of the transistors may be a thin-film transistor (TFT). At least one signal line of each set of signal lines may be connected to a gate of at least one transistor. That is, at least one signal line in each set of signal lines may be a gate line.

The plurality of transistors may be switching transistors in the display substrate, or may be drive transistors in the display substrate.

In an OLED display panel, the drive transistor may be a transistor for supplying a drive current to a light-emitting unit in a pixel driving circuit. The stability of the gate voltage of the drive transistor directly affects the stability of the drive current input to the light-emitting unit. In a liquid transistor display (LCD) panel, the drive transistor may refer to a transistor that is connected to a pixel electrode for charging the pixel electrode. The stability of the gate voltage of the drive transistor directly affects the stability of the pixel electrode during charging.

In the embodiments of the present disclosure, in order to avoid crosstalk between the signal line connected to the gate of the drive transistor and other signal lines, which affects the stability of the gate voltage of the drive transistor, crosstalk shielding may be performed, through the shielding structure, on the signal line connected to the gate of the drive transistor, thereby effectively improving the stability of the display device during operation and improving the display effect of the display device.

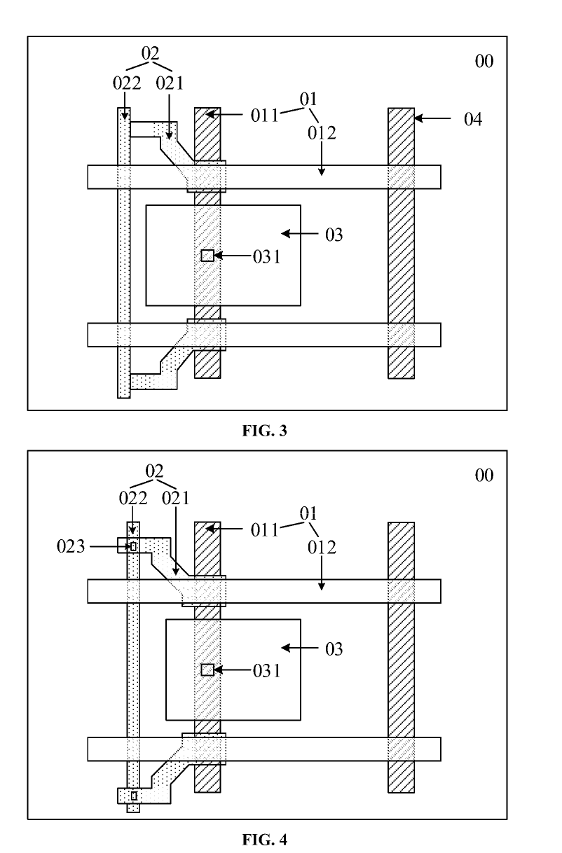

For example, as shown in FIG. 3, it is assumed that a gate 03 of a drive transistor in a certain pixel unit is connected to the first signal line 011 through a via hole 031. In order to avoid crosstalk between the first signal line 011 and the second signal line 012, a shielding portion 021 can be provided between the two signal lines.

In an optional implementation of an embodiment of the present disclosure, as shown in FIG. 1 and FIG. 3, each of the shielding structures 02 may further include a lead portion 022.

The lead portion 022 can be electrically connected to a DC power source (not shown in FIG. 3) and the shielding portion 021, respectively. That is, the lead portion 022 in each of the shielding structures 02 may be a structure for providing a DC power source signal. The shielding portion 021 may be a structure for isolating the first signal line 011 and the second signal line 012.

Optionally, as shown in FIG. 1 and FIG. 3, the lead portion 022 and the shielding portion 021 in the shielding structure 02 may be disposed in the same layer. Alternatively, as shown in FIG. 4, the lead portion 022 and the shielding portion 021 in the shielding structure 02 may be disposed in different layers, and the shielding portion 021 may be connected to the lead portion 022 through a via hole 023.

In the embodiments of the present disclosure, the arrangement orientation of the lead portion 022 and the shielding portion 021 in the shielding structure 02 can be flexibly adjusted according to the layer structure in the display substrate, so as to minimize the effect of the arrangement of the shielding structure 02 on the manufacturing process of the original layer structure. For example, the lead portions and the shielding portions in a part of shielding structures may be disposed in the same layer, and the lead portions and the shielding portions in the other part of shielding structures may be disposed in different layers.

In the embodiments of the present disclosure, the lead portion 022 may be parallel to a signal line for transmitting a non-DC signal in the display substrate.

Since a voltage fluctuation on a signal line for transmitting the non-DC signal is large, the lead portion 022 in the shielding structure 02 is disposed in parallel with the signal line, thereby avoiding an intersection of the lead portion 022 in the shielding structure 02 and the signal line, and further effectively reducing the probability of crosstalk between the shielding structure 02 and the signal line.

Optionally, as shown in FIG. 3, the lead portion 022 may be parallel to a data signal line 04 in the display substrate. The data signal line 04 may be a signal line in the display substrate that is connected to a pixel unit and provides a data signal for the pixel unit. Since the voltage of the data signal line 04 in the display panel changes greatly, the lead portion 022 in the shielding structure 02 can be disposed in parallel with the data signal line 04 in the embodiments of the present disclosure, so that the parasitic capacitance between the lead portion 022 and the data signal line 04 can be reduced as much as possible.

Optionally, in the embodiments of the present disclosure, in addition to the parallel arrangement of the lead portion 022 in the shielding structure and the signal line for transmitting the non-DC signal, a vertical distance between the lead portion 022 and the signal line for transmitting the non-DC signal may be increased as much as possible, if allowed by the wiring space, to reduce the crosstalk between the lead portion and the signal line as much as possible.

In the embodiments of the present disclosure, the display substrate may include a plurality of shielding structures. At least two of the plurality of shielding structures 02 may share one lead portion 022.

One lead portion 022 may be connected to a plurality of shielding portions 021, and each of the shielding portions 021 is located between the first signal line 011 and the second signal line 012 of the set of signal lines 01. This lead portion 022 may provide a stable DC power signal to the plurality of shielding portions 021. Thus, the number of lead portions that are required to be disposed in the display substrate is effectively reduced, which can not only avoid excessive crosstalk additionally generated by the excessive lead portions, but also effectively reduce the wiring cost of the display substrate.

Exemplarily, the display substrate shown in FIG. 5 includes two shielding structures, one of which is composed of a lead portion 022 and a shielding portion 021a disposed in the same layer, and the other one is composed of a lead portion 022 and a shielding portion 021b disposed in different layers. The shielding portion 021b is connected to the lead portion 022 through the via hole 023. The shielding portion 021a can be used to shield the crosstalk between the signal line 011 and the signal line 012. The shielding portion 021b can be used to shield the crosstalk between the signal line 011 and the signal line 013. Since the shielding portions 021a and 022b of the two shielding structures can share one lead portion 022, the crosstalk shielding between the two sets of signal lines can be realized by only disposing one lead portion 022 in the display substrate, thereby effectively reducing the wiring cost.

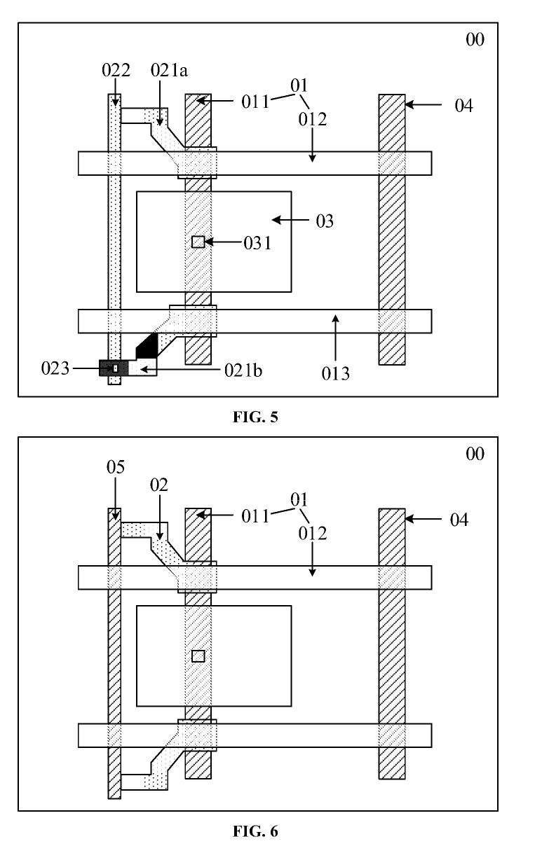

In an optional implementation of another embodiment of the present disclosure, as shown in FIG. 6, each shielding structure 02 may also be connected to a DC power source (not shown in FIG. 6) through a DC signal line 05 in the display substrate.

The DC signal line 05 may be a signal line that is electrically connected to the DC power source and used for transmitting a DC power signal in the display substrate. For example, the DC signal line 05 can be connected to a reference signal terminal or a reset signal terminal. Since the voltage of the DC signal line 05 is relatively stable, the crosstalk shielding effect can also be achieved by directly connecting the shielding structure 02 to the DC signal line 05. Moreover, the DC signal line 05, which has already existed in the display panel, is used to transmit the DC power signal, which can effectively reduce the length of the shielding structure required to be disposed in the display substrate, and avoid adding excessive wires, thereby not only reducing the wiring cost, but also reducing the crosstalk additionally introduced by the shielding structure.

Optionally, in the embodiments of the present disclosure, each shielding structure 02 may be made of a metal material, and a resistivity of the metal material is less than a preset threshold. For example, the metal material may include aluminum.

By using a metal material with a lower resistivity to form the shielding structure, it is ensured that a voltage drop of the DC power signal provided by the DC power source after transmission through the shielding structure is small, thereby ensuring the effect of crosstalk shielding.

Optionally, referring to FIG. 2, a first insulating layer 21 may be disposed between the first signal line 011 of each set of signal lines 01 and the shielding portion 021 of the corresponding shielding structure 02. A second insulating layer 22 may be disposed between the second signal line 012 of each set of signal lines 01 and the corresponding shielding portion 021. An insulating layer is disposed between each of the shielding portions 021 and an adjacent signal line so as to ensure effective insulation between the shielding portions and adjacent signal lines.

In summary, there is provided in the embodiments of the present disclosure a display substrate. The display substrate includes at least one shielding structure. A shielding portion in each shielding structure is located between two signal lines in a set of signal lines. An orthographic projection of the shielding portion on the base substrate at least partially overlaps with an overlapping region formed by the two signal lines on the base substrate. Since each of the shielding structures is electrically connected to the DC power source, the voltage on each of the shielding structures is relatively stable, thereby effectively reducing the crosstalk between the two signal lines, and ensuring the display effect of the display device.

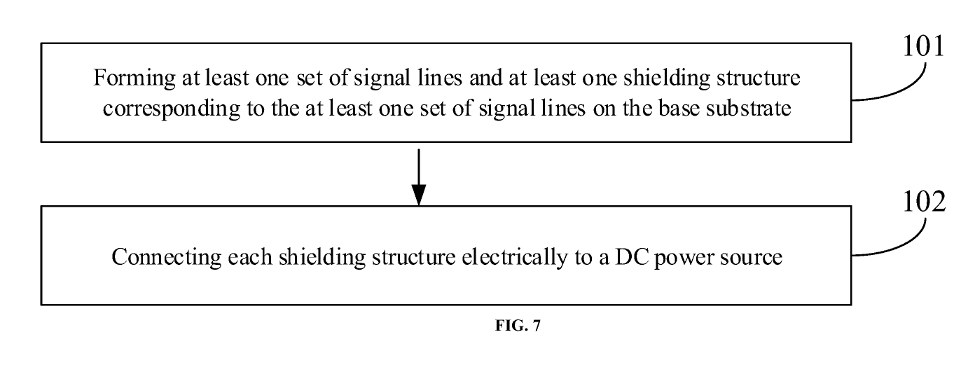

There is further provided in an embodiment of the present disclosure a method of manufacturing a display substrate, which can be used to manufacture the display substrate shown in any one of the above-described FIGS. 1 to 6. Referring to FIG. 7, the method can include the following working processes.

In step 101, at least one set of signal lines and at least one shielding structure corresponding to the at least one set of signal lines are formed on a base substrate.

In step 102, each shielding structure is electrically connected to a DC power source.

As previously described, FIGS. 1 and 2 illustrate the structure of a set of signal lines and corresponding shielding structures thereof formed on a base substrate. As can be seen from FIG. 1 and FIG. 2, each set of signal lines 01 can include a first signal line 011 and a second signal line 012 located at different layers. An orthographic projection of the first signal line 011 on the base substrate 00 and an orthogonal projection of the second signal line 012 on the base substrate 00 overlap and have an overlapping region S. Each of the shielding structures 02 includes a shielding portion 021. The shielding portion 021 is formed between the first signal line 011 and the second signal line 012 in the corresponding set of signal lines 01, and is insulated from both of the signal lines. The orthographic projection W of the shielding portion 021 in each of the shielding structures 02 on the base substrate 00 at least partially overlaps with the overlapping region S of the corresponding set of signal lines 01. For example, the orthographic projection W can cover the overlapping region S.

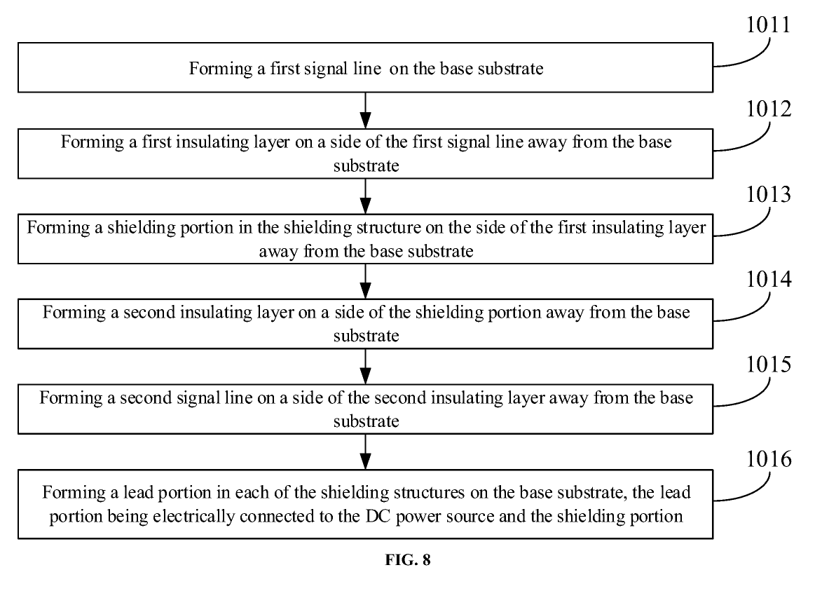

Optionally, referring to FIG. 8, a process of forming a set of signal lines and a shielding structure corresponding to the set of signal lines on a base substrate may include the following processes.

In step 1011, a first signal line is formed on the base substrate.

In step 1012, a first insulating layer is formed on a side of the first signal line away from the base substrate.

Exemplarily, as shown in FIG. 2, the first insulating layer 21 may be formed on a side of the first signal line 011 away from the base substrate 00, and the first insulating layer 21 may cover on the first signal line 011.

In step 1013, a shielding portion in the shielding structure is formed on the side of the first insulating layer away from the base substrate.

Exemplarily, as can be seen from FIG. 1 and FIG. 2, the orthographic projection of the shielding portion 021 in the shielding structure 02 on the base substrate 00 and the orthographic projection of the first signal line 011 on the base substrate 00 overlap.

In step 1014, a second insulating layer is formed on a side of the shielding portion away from the base substrate.

Exemplarily, as shown in FIG. 2, the second insulating layer 22 may be formed on a side of the shielding portion 021 away from the base substrate 00, and the second insulating layer 22 may cover on the shielding portion 021.

In step 1015, a second signal line is formed on a side of the second insulating layer away from the base substrate.

The top view of the finally formed set of signal lines 01 and the corresponding shielding structure 02 can be shown in FIG. 1, and the cross-sectional view of the set of signal lines 01 and the corresponding shielding structure 02 can be shown in FIG. 2. As can be seen from FIG. 2, the orthographic projection W of the shielding portion 021 on the base substrate 00 covers the overlapping region S formed by the orthographic projections of the first signal line 011 and the second signal line 012 on the base substrate 00.

Optionally, when forming a structure such as a shielding structure or a signal line, a metal material layer may be first formed on the base substrate, and then the metal material layer is patterned by using once-patterning process according to a pattern of the wires to be formed to obtain a corresponding structure. The once-patterning process may include steps of photoresist coating, exposure, development, etching, and stripping.

Optionally, referring to FIG. 8, the process of forming the shielding structure in the foregoing step 101 may further include the following steps.

In step 1016, a lead portion in each of the shielding structures is formed on the base substrate. The lead portion is electrically connected to the DC power source and the shielding portion, respectively.

The lead portion and the shielding portion may be formed by using once-patterning process. That is, the step 1016 may be performed in synchronization with the step 1013, in which case the lead portion and the shielding portion may be formed on the same layer of the display substrate.

Alternatively, the lead portion and the shielding portion may also be separately formed by twice-patterning processes, and then the lead portion and the shielding portion may be located at different layers of the display substrate. As shown in FIG. 4, the shielding portion 021 can be connected to the lead portion 022 through the via hole 023.

Optionally, if the lead portion 022 and the shielding portion 021 are located in different layers of the display substrate, the lead portion 022 may be formed while forming the first signal line 011. That is, the lead portion 022 and the first signal line 011 may be formed through once-patterning process. Correspondingly, the above step 1016 can be performed in synchronization with the step 1011.

Alternatively, the lead portion 022 may be formed while forming the second signal line 012. That is, the lead portion 022 and the second signal line 012 may also be formed by once-patterning process. Correspondingly, the above step 1016 can be performed in synchronization with the step 1015.

Optionally, the display substrate may further include a plurality of transistors disposed on the base substrate. In each set of signal lines formed in the above manufacturing method, at least one signal line may be formed in the same layer as a gate of at least one transistor by once-patterning process and may be connected to the gate. That is, at least one signal line in each set of signal lines may be a gate line.

If a certain signal line in the display substrate is connected to the gate of the transistor, a shielding structure corresponding to the signal line may be formed in the display substrate, and the shielding portion in the shielding structure is formed at an overlapping portion between the signal line and other signal lines.

Optionally, when the lead portion 022 is formed, the direction of the lead portion 022 may be determined according to the direction of the signal line for transmitting the non-DC signal in the display substrate, so that the length direction of the lead portion 022 may be parallel to the signal line (for example, data signal line) for transmitting the non-DC signal in the display substrate.

Optionally, when there is a plurality of shielding structures to be formed in the display substrate, one lead portion and at least two shielding portions may be formed on the base substrate, and each of the at least two shielding portions is respectively connected to the lead portion, so that the at least two shielding portions can share one lead portion.

Optionally, when the shielding structure is formed, the shielding structure may be directly connected to a DC signal line in the display substrate. The DC signal line may transmit a DC power signal to the shielding portion in the shielding structure.

It should be understood that the sequence of the steps in the method for manufacturing a display substrate provided by the embodiments of the present disclosure may be appropriately adjusted, and the steps may also be correspondingly increased or decreased as required. Within the technical scope of the present disclosure, any method that can be easily conceived by those skilled in the art shall be included in the protection scope of the present disclosure, and therefore will not be described again.

In summary, there is provided in the embodiments of the present disclosure a method for manufacturing a display substrate. In this method, at least one shielding structure may be formed on a base substrate. Each shielding structure is electrically connected to a DC power source. A shielding portion in each shielding structure is located between a first signal line and a second signal line in a set of signal lines. An orthographic projection of the shielding portion on the base substrate at least partially overlaps with an overlapping region formed by the two signal lines on the base substrate. Since the voltage on each of the shielding structures is relatively stable, crosstalk between the two signal lines in the set of signal lines can be effectively reduced, and the display effect of the display device can be ensured.

There is further provided in an embodiment of the present disclosure a display panel, including the display substrate shown in any one of FIG. 1 to FIG. 6.

There is further provided in an embodiment of the present disclosure a display device. The display device may include the display panel shown in any one of FIG. 1 to FIG. 6. The display device may be a liquid crystal panel, an electronic paper, an OLED panel, an AMOLED panel, a mobile phone, a tablet computer, a TV, a display, a laptop, a digital photo frame, a navigator or any other product or part with a display function.

The foregoing descriptions are merely optional embodiments of the present disclosure, and are not intended to limit the protection scope of the present disclosure. Within the spirit and principles of the disclosure, any modifications, equivalent substitutions, improvements, etc., shall fall into the protection scope defined by the claims appended to the present disclosure.

What is claimed is:

1. A display substrate comprising:
at least one set of signal lines and at least one shielding structure corresponding to the at least one set of signal lines disposed on a base substrate, the shielding structure being electrically connected to a DC power source, and the shielding structure comprising a shielding portion,
wherein each set of signal lines comprises a first signal line and a second signal line that are located at different layers, and orthographic projections of the first signal line and the second signal line on the base substrate overlap and have an overlapping region; and
the shielding portion is located between the first signal line and the second signal line, and is insulated from both the first signal line and the second signal line, and an orthographic projection of the shielding portion on the base substrate at least partially overlaps the overlapping region.

2. The display substrate of claim 1, wherein the orthographic projection of the shielding portion on the base substrate covers the overlapping region.

3. The display substrate of claim 1, further comprising:
a plurality of transistors disposed on the base substrate,
wherein at least one signal line of each set of signal lines is connected to a gate of at least one of the transistors.

4. The display substrate of claim 1, wherein the shielding structure further comprises: a lead portion electrically connected to the DC power source and the shielding portion, respectively.

5. The display substrate of claim 4, wherein the lead portion is disposed in the same layer as the shielding portion.

6. The display substrate of claim 4, wherein the lead portion is disposed in a different layer from the shielding portion, and the shielding portion is connected to the lead portion through a via hole.

7. The display substrate of claim 4, wherein the lead portion and a signal line for transmitting a non-DC signal in the display substrate are parallel to each other.

8. The display substrate of claim 7, wherein the lead portion and data signal line in the display substrate are parallel to each other.

9. The display substrate of claim 4, comprising: a plurality of shielding structures, wherein at least two of the plurality of shielding structures share one lead portion.

10. The display substrate of claim 1, wherein the shielding structure is electrically connected to the DC power source through a DC signal line in the display substrate.

11. The display substrate of claim 1, wherein the shielding structure is made of a metal material.

12. A method for manufacturing a display substrate, comprising steps of:
forming at least one set of signal lines and at least one shielding structure corresponding, to the at least one set of signal lines on a base substrate, the shielding structure comprising a shielding portion; and
connecting electrically the shielding structure to a DC power source;
wherein each set of signal lines comprises a first signal line and a second signal line that are located at different layers, and orthographic projections of the first signal line and the second signal line on the base substrate overlap and have an overlapping region; and
the shielding portion is located between the first signal line and the second signal line, and is insulated from both the first signal line and the second signal line, and an orthographic projection of the shielding portion on the base substrate at least partially overlaps the overlapping region.

13. The method of claim 12, wherein the orthographic projection of the shielding portion in the shielding structure on the base substrate covers the overlapping region.

14. The method of claim 12, wherein a plurality of transistors are further formed on the base substrate; and
at least one signal line in each set of signal lines is formed in the same layer as a gate of at least one of the transistors, and is connected to the gate.

15. The method of claim 12, wherein the step of forming at least one set of signal lines and at least one shielding structure corresponding to the at least one set of signal lines on the base substrate comprises steps of:
forming a first signal line on the base substrate;
forming a first insulating layer on a side of the first signal line away from the base substrate;
forming a shielding portion in the shielding structure on the side of the first insulating layer away from the base substrate;
forming a second insulating layer on a side of the shielding portion away from the base substrate; and
forming a second signal line on a side of the second insulating layer away from the base substrate;
wherein the first signal line and the second signal line constitute the set of signal lines.

16. The method of claim 12, wherein the step of forming the shielding structure on the base substrate further comprises step of:
forming a lead portion in the shielding structure on the base substrate, the lead portion being electrically connected to the DC power source and the shielding portion, respectively;
wherein the lead portion is formed in the same layer as the shielding portion.

17. The method of claim 12, wherein the step of forming the shielding structure on the base substrate further comprises step of:
forming a lead portion in the shielding structure on the base substrate, the lead portion being electrically connected to the DC power source and the shielding portion, respectively;
wherein the lead portion is formed in a different layer from the shielding portion, and the shielding portion is connected to the lead portion through a via hole.

18. The method of claim 17, wherein the step of forming the lead portion in the shielding structure on the base substrate comprises step of:
forming the lead portion when the first signal line is formed.

19. The method of claim 17, wherein the step of forming the lead portion in the shielding structure on the base substrate comprises step of:
forming the lead portion when the second signal line is formed,

20. A display panel, comprising: a display substrate, and the display substrate comprising:
at least one set of signal lines, and at least one shielding structure corresponding to the at least one set of signal lines disposed on a base substrate, the shielding structure being electrically connected to a DC power source, and the shielding structure comprising a shielding portion;
wherein each set of signal lines comprises a first signal line and a second signal line that are located at different layers, the orthographic projections of the first signal line and the second signal line on the base substrate overlap and leave an overlapping region; and
the shielding portion is located between the first signal line and the second signal line, and is insulated from both the first signal line and the second signal line, and an orthographic projection of the shielding portion on the base substrate at least partially overlaps the overlapping region.
